(19) United States
(12) Patent Application Publication
(10) Pub. No.: US 2026/0244232 A1
(43) Pub. Date: Aug. 20, 2026

(54) METHOD AND APPARATUS FOR REDUCING POWER CONSUMPTION IN A REFERENCE BUFFER CIRCUIT

(71) Applicant: Analog Devices International Unlimited Company, Limerick (IE)

(72) Inventors: Maitrey Kamble, Mumbai (IN); Sai Krishna Vallury, Visakhapatnam (IN)

(21) Appl. No.: 19/054,387

(22) Filed: Feb. 14, 2025

(51) Int. Cl. G05F 1/575

(52) U.S. Cl. CPC G05F 1/575

(57) ABSTRACT

There is provided methods and apparatuses for reducing power consumption in a reference buffer circuit, comprising: receiving, at an amplifier of the reference circuit, a first signal from a reference voltage source; receiving, at the amplifier of the reference circuit, a second signal from a power supply; outputting, by the amplifier of the reference circuit, a voltage reference to an analog-to-digital converter, ADC; and controlling a power supply to the amplifier by feeding back a control signal representative of an operational phase of the ADC to the power supply.

### FIELD

This application relates generally to methods and apparatuses for reducing power consumption of a reference buffer and, in particular but not exclusively, to methods and apparatus for reducing power consumption of a reference buffer having an on-chip load capacitor.

### BACKGROUND

A reference circuit is a circuit that provides a stable reference voltage to another circuit, such as an analog-to-digital converter (ADC) or a digital-to-analog converter (DAC). It ensures that the reference voltage remains constant despite variations in load or supply voltage.

During the conversion process, ADCs and DACs themselves can cause transient loads on the reference voltage. Reference circuits help in quickly settling these transients, ensuring that the reference voltage remains stable and accurate throughout the conversion.

ADCs and DACs often also need to drive capacitive or resistive loads with a stable and accurate voltage reference. Again, reference circuits can help by providing the necessary drive capability to maintain a stable reference voltage despite these varying loads.

Various reference buffers have been proposed using an amplifier together with an off-chip load capacitor. A large capacitance is needed to limit the bandwidth of the reference buffers and to minimize noise. However, several problems exist with this solution including, but not limited to, remaining on for a greater amount of time and thus increased power consumption.

Therefore, it is desirable to provide a reference circuit having a reduced power consumption.

### SUMMARY OF THE DISCLOSURE

The systems and methods of the present disclosure provide ways in which to reduce power consumption of a reference buffer having an on-chip loading capacitor.

In one aspect of the present disclosure, there is provided method of reducing power consumption in a reference circuit, the method comprising: receiving, at an amplifier of the reference circuit, a first signal from a reference voltage source; receiving, at the amplifier of the reference circuit, a second signal from a power supply; outputting, by the amplifier of the reference circuit, a voltage reference to an analog-to-digital converter, ADC; and controlling a power supply to the amplifier by feeding back a control signal representative of an operational phase of the ADC to the power supply.

The first signal may be received at a first input of the amplifier and the second signal may be received at a second input of the amplifier. The voltage reference may be output from an output of the amplifier, and the output signal may be based upon the first signal and the second signal. Since the power supply to the amplifier is controlled by feeding back a control signal representative of an operational phase of the ADC to the power supply, and the second signal received at input of the amplifier comes from the power supply, the control signal is fed back into the amplifier as part of the second signal. Therefore, the power consumption of the amplifier can be dynamically adjusted based on the operational phase of the ADC, leading to more efficient power usage and reduced overall power consumption in the reference circuit.

The control signal is representative of an operational phase of the ADC. In some examples, the operation phases of the ADC may include an acquisition phase, a conversion phase and a residue amplification stage. Typically, during the acquisition phase, the control signal may reduce the power supply to the amplifier, as this phase typically requires less power, during the conversion phase, the control signal may increase the power supply to ensure accurate and efficient conversion, and during the residue amplification stage, the control signal may adjust the power supply to balance between power efficiency and performance.

The method may further comprise determining the control signal using digital control circuitry. The digital control circuitry may be designed to precisely generate the control signals based on the operational phases of the ADC. By utilizing digital control, the system can achieve high accuracy and flexibility in managing the power supply. The digital control circuitry may also be programmed to adapt to different ADC configurations and operational requirements, ensuring optimal power management and performance across various applications.

The control signal may be received from a timing circuit or timer. An ADC, for example a SAR ADC, may operate using an asynchronous state machine. Using a timing circuit in a SAR ADC may offer several benefits. For example, it ensures efficient power management by dynamically adjusting the power supply, maintains precise timing for each phase, and provides flexibility to adapt to different operational requirements and power saving strategies.

The timing circuit may provide control signals in order to manage the conversion process of a converter. The timing circuit may initialize the conversion process by resetting the SAR logic and setting the initial conditions for the ADC.

The timing circuit may receive an edge of an external clock and begin conversion of the ADC. It can produce various digital control signals that represent different phases of ADC's conversion as the underlying state machine transitions from its various states. Eventually, as all the bit trials are completed, the timing circuit shuts down the ADC so that it goes into acquisition phase and then shuts down itself. Therefore, the control signal of the present disclosure can be one of the many control signals generated by the timing circuit, which corresponds to one of the several phases of ADC's conversion.

In the example of a SAR ADC, during a sampling phase, the timing circuit may control the sample-and-hold circuit, allowing the analog input voltage to be sampled and held steady for conversion. The timing circuit may then orchestrate the successive approximation process, which involves setting the most significant bit (MSB) of the digital output and triggering the comparator to compare the held analog input voltage with the DAC output. Based on the comparator's output, the timing circuit may adjust the SAR register by either keeping the MSB or clearing it, then moves to the next bit. This process may repeat for each bit from MSB to the least significant bit (LSB), with the timing circuit controlling the timing of each comparison and adjustment.

Once all bits are determined, the timing circuit may signal the end of the conversion process, and the final digital output is available. The timing circuit may generate control signals that represent the operational phases of the ADC, such as the conversion phase, acquisition phase, and residue amplification phase. One or more of these control signals are fed back to the power supply to manage the power consumption of the amplifier.

The timing circuit can also dynamically adjust the power supply based on the ADC's operational phases, reducing power during less critical phases (e.g., acquisition phase) and increasing power during critical phases (e.g., conversion phase). It can also signal the power supply to power down certain parts of the amplifier when they are not needed, thereby saving power.

Controlling the power supply to the amplifier may comprise controlling a bias current input from the power supply to the second input of the amplifier. By adjusting the bias current input to the amplifier from the power supply, the method can fine tune the power consumption of the amplifier, ensuring that it operates efficiently under various operational phases.

Controlling the power supply to the amplifier may comprise individually powering down individual slices of the amplifier. This technique, which may be referred to as ‘slice-based power management’, enables the method to deactivate specific portions of the amplifier when they are not needed. By selectively powering down these individual slices, the overall power consumption can be significantly reduced without compromising the performance of the amplifier during critical phases. This method also helps in minimizing heat generation and extending the lifespan of the individual amplifier slices.

Controlling the power supply to the amplifier may comprise changing the power supply to the amplifier from a first level to a second level. This dynamic adjustment allows the method to optimize the power consumption of the amplifier based on the operational phase of the amplifier. For instance, during periods of high demand or critical operations, the power supply can be increased to ensure optimal performance. Conversely, during less critical phases, the power supply can be reduced to conserve energy. This approach not only enhances the efficiency of the amplifier but also contributes to the overall power management strategy of the reference circuit.

When changing the power supply to the amplifier from a first level to a second level, the first level may be higher than the second level. By reducing the power supply to a lower level during less critical phases, such as the acquisition phase, the system can conserve energy and reduce heat generation. Conversely, during more critical phases, such as the conversion phase, the power supply can be increased to ensure optimal performance and accuracy. This dynamic power management strategy helps in achieving a balance between power efficiency and performance of the reference circuit.

In some examples, the operational phase of the ADC may comprise a conversion phase. Therefore, feeding back the control signal may comprise feeding back the control signal representative of a conversion phase of the ADC.

The conversion phase of the ADC may comprise multiple stages.

In some examples, the conversion phase of the ADC may comprise a first conversion stage. The first conversion stage may comprise converting a most significant bit, MSB.

In some examples, the conversion phase of the ADC may comprise a second conversion stage, and controlling a power of the amplifier may comprises reducing the power supply to the amplifier from the first conversion stage to the second conversion stage. The second conversion stage may comprise converting a least significant bit, LSB.

Additionally, during the conversion phase, the control signal can dynamically adjust the power supply to optimize the performance of the amplifier. For instance, higher power levels may be required during the MSB conversion to ensure accuracy, while lower power levels may suffice during the LSB conversion to conserve energy. This dynamic adjustment helps in maintaining the balance between power efficiency and conversion accuracy.

Furthermore, the control signal can also manage other aspects of the amplifier's operation, such as biasing and gain settings, to further enhance the performance during different stages of the conversion phase.

In some examples, the operational phase of the ADC may comprise an acquisition phase. Therefore, feeding back the control signal may comprise feeding the control signal representative of an acquisition phase of the ADC, and controlling a power of the amplifier may comprise reducing the power supply to the amplifier from a conversion phase to the acquisition phase.

During the acquisition phase, the power requirements are typically lower compared to the conversion phase. By reducing the power supply during this phase, the system can conserve energy and minimize heat generation. This approach ensures that the amplifier operates efficiently without compromising the accuracy of the signal acquisition.

Additionally, the control signal can manage other parameters of the amplifier, such as biasing and gain settings, to further optimize performance during the acquisition phase. This dynamic adjustment helps in maintaining the stability and reliability of the reference circuit, ensuring consistent and accurate operation across different phases of the ADC.

In some examples, the operational phase of the ADC may comprise a residue amplification phase. Therefore, feeding back the control signal may comprise feeding the control signal representative of a residue amplification phase of the ADC, and controlling a power of the amplifier may comprise reducing the power supply to the amplifier from a conversion phase to the residue amplification phase.

During the residue amplification phase, the power requirements are typically lower than during the conversion phase. By reducing the power supply during this phase, the system can conserve energy and minimize heat generation, contributing to overall power efficiency. This dynamic adjustment ensures that the amplifier operates efficiently without compromising the accuracy and integrity of the residue amplification process.

Additionally, the control signal can manage other parameters of the amplifier, such as biasing and gain settings, to further optimize performance during the residue amplification phase. This fine-tuning helps maintain the stability and reliability of the reference circuit, ensuring consistent and accurate operation across all phases of the ADC.

The method may further comprise driving an on-chip load capacitor at the output of the amplifier.

The on-chip load capacitor may help in stabilizing the output voltage and improving the overall performance of the amplifier. By providing a stable load, the capacitor can reduce voltage fluctuations and noise, ensuring a more accurate and reliable voltage reference for the ADC.

Additionally, the on-chip load capacitor can enhance the response time of the amplifier as well as its transient performance, making it more effective in handling fast changes in the input signal. This improvement can be particularly beneficial in high-speed ADC applications, for which maintaining signal integrity is important. Furthermore, integrating the load capacitor on-chip can save space and reduce the complexity of the circuit design, leading to a more compact and efficient reference circuit.

In another aspect of the present disclosure, there is provided a reference circuit, comprising: an amplifier configured to act as a voltage amplifier, the amplifier having a first input configured to receive a first signal from a reference voltage source, a second input configured to receive a second signal from a power supply, and an output configured to provide a voltage reference to an analog-to-digital converter, ADC, wherein a control signal representative of an operational phase of the ADC is configured to be fed back to the power supply in order to control a power supply to the amplifier.

The amplifier has two inputs and an output. The first signal is received at the first input of the amplifier and the second signal is received at the second input of the amplifier. The voltage reference is output from an output of the amplifier, and the output signal is based upon the first signal and the second signal. Since a control signal representative of an operational phase of the ADC is configured to be fed back to the power supply, and the second signal received at input of the amplifier comes from the power supply, the control signal is fed back into the amplifier as part of the second signal. Therefore, the power consumption of the amplifier can be dynamically adjusted based on the operational phase of the ADC, leading to more efficient power usage and reduced overall power consumption in the reference circuit.

The reference circuit may further comprise digital control circuitry for determining the control signal. The digital control circuitry can be designed to precisely generate the control signals based on the operational phases of the ADC, ensuring accurate and flexible power management. By utilizing digital control, the system can adapt to different ADC configurations and operational requirements, thus optimizing power usage and performance of the reference circuit.

The reference circuit may further comprise generating the control circuitry using the digital control circuitry. This approach allows for the incorporation of advanced control algorithms and adaptive power management strategies, enhancing the overall efficiency and reliability of the reference circuit. The digital control circuitry may also help in facilitating real-time adjustments to the power supply, ensuring that the amplifier operates optimally under various operational phases.

The reference circuit may further comprise an on-chip load capacitor at the output of the amplifier. The on-chip load capacitor may help in stabilizing the output voltage and improving the overall performance of the amplifier by reducing voltage fluctuations and noise.

The reference circuit may further comprise the power supply. This may advantageously result in a compact design and allows for more precise control over the power management, enhancing the efficiency and reliability of the system.

The amplifier may comprise an operational amplifier. Operational amplifiers may provides high gain and stability, making them suitable for applications requiring precise voltage amplification and voltage reference generation.

The amplifier may comprise a source follower, configured to separate a voltage gain stage and a transconductance device. This configuration may enhance the overall linearity and stability of the amplifier, ensuring accurate voltage amplification with minimal distortion.

The amplifier may comprise a unity gain buffer amplifier. A unity gain buffer amplifier may provide high input impedance and low output impedance, making it advantageous for buffering and isolating different stages of the circuit. This helps in maintaining signal integrity and reducing the loading effect on the previous stage.

The amplifier may comprise amplifier slices, each slice being configured to be powered down individually. A slice-based power management allows for selective deactivation of specific portions of the amplifier when they are not needed, significantly reducing power consumption. By powering down individual slices, the system can optimize power usage without compromising performance during critical operational phases of the ADC.

In another aspect of the present disclosure, there is provided a successive approximation register analog-to-digital converter, SAR ADC, comprising the reference circuit of any of the previous examples and the SAR ADC.

A skilled person would recognize that the methods and circuits of the present disclosure may also apply to other ADCs aside from SAR ADC.

### Definitions

A ‘reference buffer’ is a circuit that provides a stable reference voltage to another circuit. It is typically implemented as an amplifier, for example, and operational amplifier, that provides voltage buffering, acting as a voltage follower.

An ADC may have various operational phases that are determined by its internal architecture. The operational phases may include, inter alia, an acquisition phase, a conversion phase and a residue amplification stage. During the ‘acquisition phase’, an internal Sample-and-Hold (S/H) circuit of the ADC connects to the input voltage and the S/H capacitor charges to the input voltage level. During the ‘conversion phase’, the ADC may convert the held voltage into a digital value and the conversion process can vary depending on the type of ADC (e.g., SAR, Delta-Sigma, Flash). The ‘residue amplification stage’ refers amplifying a residue after the conversion of one of multiple stages of an ADC so as to ensure that it is within an appropriate range for the next stage.

### FIGURES

Aspects of the present disclosure are described, by way of example only, with reference to the following drawings, in which:

FIG. 1 shows a block diagram of a reference buffer;

FIG. 2 shows a block diagram of a reference circuit in accordance with an example of the present disclosure;

FIG. 3 shows a block diagram of a reference circuit in accordance with an example of the present disclosure;

FIG. 4 is a table showing characteristics of an amplifier of a reference circuit in accordance with the present disclosure;

FIG. 5 is a graph showing performance of a reference circuit in accordance with an example of the present disclosure;

FIG. 6 illustrates the operation of an example reference circuit in accordance with an example of the present disclosure;

FIG. 7 illustrates the operation of a reference circuit in accordance with an example of the present disclosure;

FIG. 8 illustrates the operation of an example reference circuit in accordance with an example of the present disclosure; and

FIG. 9 represents method steps in accordance with an example of the present disclosure.

### DETAILED DESCRIPTION

Simple techniques for implementing reference buffers involve an amplifier used in conjunction with an off-chip load capacitor. However, the capacitance of the load capacitor, being a large external discrete component, can often be in the range of few microfarads. The purpose of this high capacitance is to ensure that the load capacitor becomes a dominant pole of the amplifier, and the internal non-dominant poles can easily be pushed a decade or more beyond the unity-gain-frequency (UGF) of the amplifier, for example, limited between several hundreds of KHz to a few MHz. The large open-loop gain of the amplifier helps in minimizing gain-error of the reference buffer and therefore the overall system. However, such amplifiers cannot be power-cycled and power consumption can be high since the power-up time as well as the transient settling time-constant are prohibitively large.

In other techniques, it has been proposed to use an on-chip load capacitor outside of the feedback loop instead of an off-chip load capacitor. A switch may be closed in order to allow an appropriate biasing voltage to be stored on the on-chip load capacitor. Then, when a reference voltage is required by the ADC, the switch can be opened, such that the amplifier loop remains undisturbed during transient settling of the reference voltage. The capacitor in this arrangement can be small enough to be realized in a monolithic manner. Therefore, this architecture does not require a large external capacitor. However, the main limitation of this architecture arises from the fact that DC accuracy is limited by the matching between transistors on either side of the switch.

Further, power cycling or reference pre-charging have been used in the past. However, these techniques come at expense of speed of operation and/or die-area.

As described in the background section, reference buffers are critical components in ADC and DAC systems, ensuring that the reference voltage remains stable, accurate, and low-noise, which is essential for precise digital-to-analog and analog-to-digital conversions, and it is desirable to provide a reference buffer having a reduced power consumption.

The present inventors have recognised that improvements can be made to the power consumption of a reference buffer having an on-chip loading capacitor in view of several factors relating to the noise profile of reference buffer. Firstly, the present inventors have found that noise of the reference buffer is independent of current input into the amplifier; instead, noise is dependent on the load capacitance value. Secondly, the present inventors have found that low noise requirements of the reference buffer are more important during certain phases of operation of the ADC. In view of these findings, the present inventors propose a scheme whereby power expenditure of the reference buffer is different depending upon an operational phase of the ADC: a) the power expenditure of the reference buffer during the phase(s) that require transient settling should be as much as required to achieve the aforesaid settling requirement; b) however, the power consumption of the reference buffer can be reduced during the other phases of ADC's operation where either the settling requirements are relaxed or only noise performance matters. This is done by feeding back a control signal based on an operational phase of the ADC to the power supply in order to control an input current to the amplifier. Essentially, the power consumption of the amplifier is proposed to change with respect to the phase of operation of the ADC. Further, power reduction techniques for the reference buffer are proposed in a manner which does not compromise the noise performance of the amplifier.

In the present disclosure, the power consumption of the amplifier is proposed to change with respect to the phase of operation of the ADC. The power reduction is proposed in a manner which does not compromise the noise performance of the amplifier.

ADCs and DACs operate with respect to a reference voltage (V_{REF}). Very often, the internal architecture of the ADCs and DACs are such that the entity that needs to provide the reference voltage to these classes of circuits, has to drive either a capacitive or resistive load, depending upon the internal architectural details of these converters.

Therefore, there is often a specification with respect to transient settling behavior and noise performance on the V_{REF} of an ADC or DAC. The bandgap references, which often generate a stable reference voltage in the system, are circuits that mostly exhibit low-bandwidth and high noise-spectral-density (NSD), due to their architectural limitations/virtues.

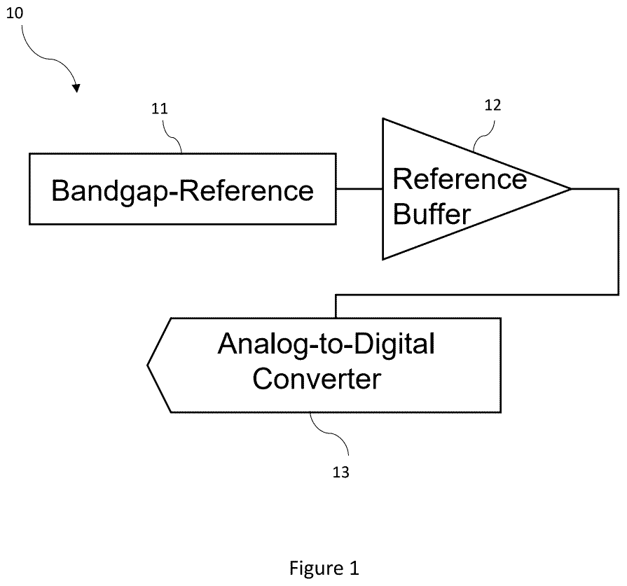

Hence, in many cases, the provision of V_{REF} to ADCs or DACs is performed done via amplifiers known as a reference circuit 10 and an example block diagram of this arrangement driving an ADC is depicted in FIG. 1. In FIG. 1, the reference circuit 10 comprises a bandgap reference 11, a reference buffer 12 and an ADC 13.

The bandgap reference 11 can provide a stable value of V_{REF} but it may exhibit low bandwidth and high (NSD) due to its architectural limitations. In order to address these limitations, a reference buffer 12 may be used to provide the V_{REF} to the ADC 13. The reference buffer 12 of FIG. 1 is essentially an amplifier having unity gain that drive either a capacitive or resistive load, depending on the internal architecture of the converters. However, the present invention is also applicable to reference buffers that exhibit voltage gains greater than unity. The reference buffer 12 ensures that the V_{REF} is stable and has the required transient settling behavior and noise performance.

As mentioned above, there is a desire for a reference circuit that achieves one or more of the following:
a. Drives a large on-chip de-coupling capacitor;
b. Ensures transient settling requirement of each bit-trial on standalone (and not average) basis;
c. Meets the required total-integrated-noise target of the system; and
d. Requires a low die-area.

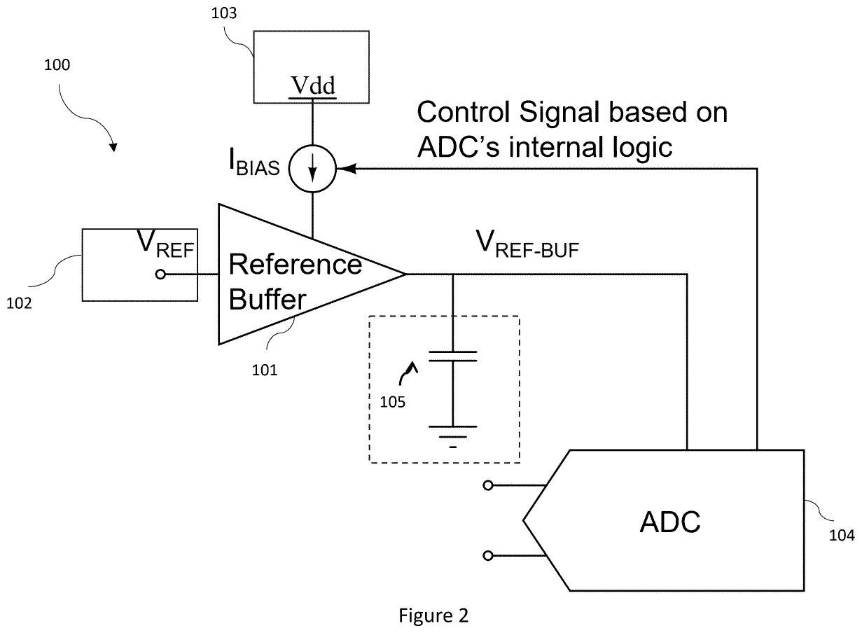

FIG. 2 shows a reference circuit 100 in accordance with an example of the present disclosure.

The reference circuit 100 is designed to reduce power consumption in an amplifier 101, which in this example is depicted as comprising a reference buffer operational amplifier 101. The circuit includes an amplifier that receives a first signal at a first input from a reference voltage source 102 and a second signal at a second input from a power supply 103 with voltage Vdd and introducing a bias current. One way in which to control the bias current may be to change the trim codes of the reference buffer, depending on the operational phase or operational sub-phase of the ADC. The amplifier outputs a voltage reference to an ADC 104. A control signal, which is representative of an operational phase of the ADC 104, is fed back to the power supply 103 to control the power supply to the amplifier 101.

The reference circuit 100 may further include digital control circuitry to determine the control signal based on an operational phase of the ADC 104. The digital circuitry can generate precise control signals based on the operational phases(s) of the ADC 104, ensuring accurate and flexible power management of the reference circuit 100.

The dynamic adjustment of power supply 103 to the amplifier 101 based on the operational phase of the ADC 104 is advantageous in achieving more efficient power usage and reduced overall power consumption in the reference circuit 100. This may involve changing the power supply 103 to the amplifier 101 from a first level to a second level, wherein in some examples the first level is higher than the second level. This will be explained further below with respect to various operational phases of the ADC 104.

When a control signal representative of a conversion phase of the ADC 104 is fed back to the second input of the amplifier, this may represent an operational phase of the ADC 104 that is relatively power intensive.

Within a conversion phase of the ADC 104, there may be a first conversion stage and a second conversion stage. In this example, the first conversion stage comprises converting a most significant bit, MSB, and the second conversion stage comprises converting a least significant bit, LSB. Thus, controlling a power of the amplifier comprises reducing the power supply to the amplifier from the first conversion stage to the second conversion stage by adjusting the bias current to the second input of the amplifier 101.

When a control signal representative of an acquisition phase of the ADC 104, this may represent an operational phase of the ADC 104 that is less power intensive than a conversion phase. Therefore, controlling a power of the amplifier comprises reducing the power supply to the amplifier from a conversion phase to the acquisition phase by adjusting the bias current to the second input of the amplifier 101.

When a control signal representative of a residue amplification phase of the ADC 104, this may represent an operational phase of the ADC 104 that is less power intensive than a conversion phase. Therefore, controlling a power of the amplifier comprises reducing the power supply to the amplifier from a conversion phase to the residue amplification phase by adjusting the bias current to the second input of the amplifier 101.

An on-chip load capacitor 105 is also shown in FIG. 2 as an optional feature at the output of the amplifier 101, which can help in stabilizing the output voltage, reducing noise, and improving overall performance.

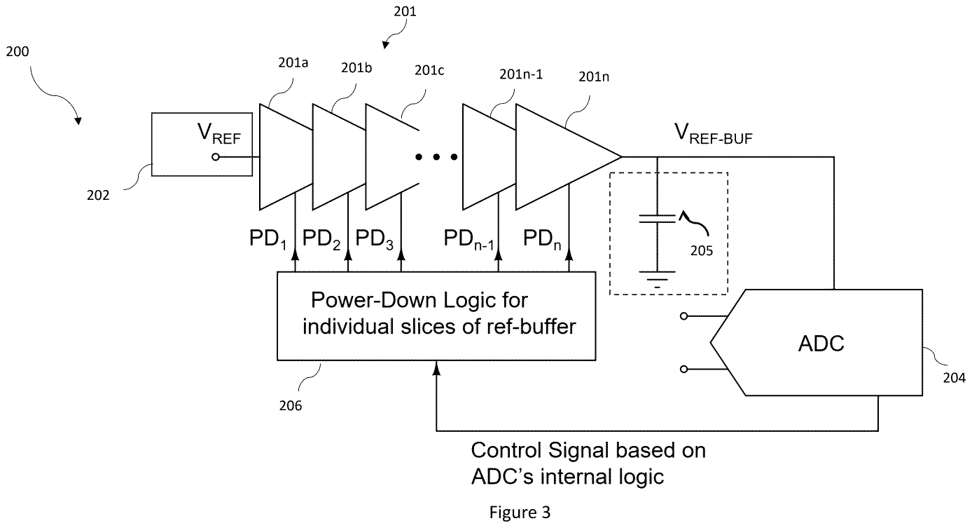

FIG. 3 shows a reference circuit 200 in accordance with an example of the present disclosure.

The reference circuit 200 is designed to reduce power consumption in an amplifier 201, which in this example is depicted as comprising a reference buffer as the amplifier 201. The circuit includes an amplifier that receives a first signal at a first input from a reference voltage source 202 and a second signal at a second input from a power supply 203 with voltage Vdd. The amplifier outputs a voltage reference to an ADC 204. A control signal, which is representative of an operational phase of the ADC 204, is fed back to the power supply 203 to control the power supply to the amplifier 201.

The reference circuit 200 may further include digital control circuitry to determine the control signal based on an operational phase of the ADC 204. The digital circuitry can generate precise control signals based on the operational phases(s) of the ADC 204, ensuring accurate and flexible power management of the reference circuit 200.

The dynamic adjustment of power supply 203 to the amplifier 201 based on the operational phase of the ADC helps in achieving more efficient power usage and reduced overall power consumption in the reference circuit 200. The amplifier 201 comprises slices 201 a . . . 201n that can be powered down individually depending on the operational phase or operational sub-phase of the ADC, thus allowing for selective deactivation of specific portions of the amplifier 201 to reduce power consumption of the reference circuit 200 without compromising its performance. This may involve changing the power supply 203 to the amplifier 201 from a first level to a second level, wherein in some examples the first level is higher than the second level. This will be explained further below with respect to various operational phases of the ADC 204.

When a control signal representative of a conversion phase of the ADC 104 is fed back to the second input of the amplifier, this may represent an operational phase of the ADC 104 that is relatively power intensive.

Within a conversion phase of the ADC 104, there may be a first conversion stage and a second conversion stage. In this example, the first conversion stage comprises converting a most significant bit, MSB, and the second conversion stage comprises converting a least significant bit, LSB. Thus, controlling a power of the amplifier comprises reducing the power supply to the amplifier from the first conversion stage to the second conversion stage by powering down individual slices 201a . . . 201n of the amplifier 201.

When a control signal representative of an acquisition phase of the ADC 104, this may represent an operational phase of the ADC 104 that is less power intensive than a conversion phase. Therefore, controlling a power of the amplifier comprises reducing the power supply to the amplifier from a conversion phase to the acquisition phase by powering down individual slices 201a . . . 201n of the amplifier 201.

When a control signal representative of a residue amplification phase of the ADC 104, this may represent an operational phase of the ADC 104 that is less power intensive than a conversion phase. Therefore, controlling a power of the amplifier comprises reducing the power supply to the amplifier from a conversion phase to the residue amplification phase by powering down individual slices 201a . . . 201n of the amplifier 201.

An on-chip load capacitor 205 is also shown in FIG. 2 as an optional feature at the output of the amplifier 201, which can help in stabilizing the output voltage, reducing noise, and improving overall performance.

In some examples, based on settling requirements and chip-area budget, a value of 160 pF for the on-chip load-capacitor (C_{L}) of the amplifier 101, 201 may be chosen. To achieve a first-order transient response at minimum power consumption, load-compensation may be utilized for the amplifier 101, 201.

Further, to minimize the power-consumption, the amplifier may have a simple architecture of one voltage gain-stage a gₘ stage and one current gain stage. Since C_{L} may be a small, on-chip component, a source follower based unity-gain stage of the amplifier 101, 201 to separate the voltage gain stage and the gₘ devices may be advantageous.

The present inventors have found that the first order, the total integrated noise of the amplifier is largely independent of the overall current consumption, voltage gain of the first stage, and the value of the gₘ; instead, it is solely dependent on the load-capacitance value. In absence of peaking of NSD of all the key contributors, the noise equivalence of this circuit is similar to an RC filter, where the total-integrated-noise is irrespective of the value of resistor ‘R’.

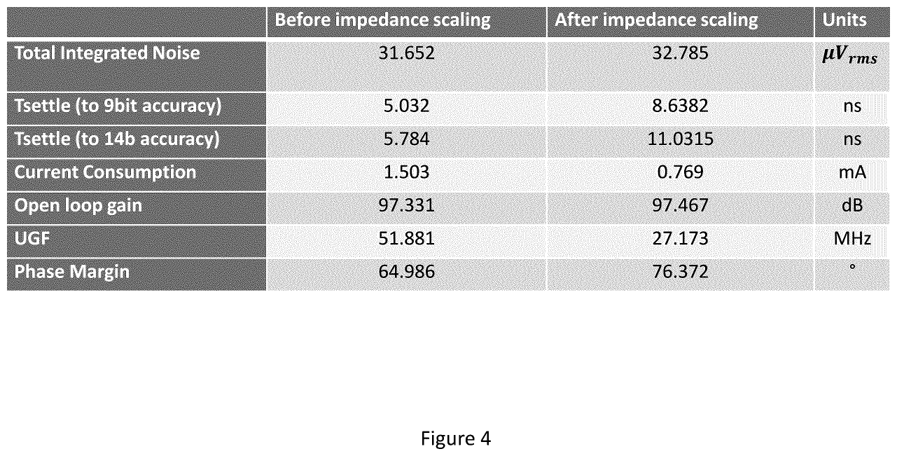

FIG. 4 is a table showing the effect of impedance scaling of the amplifier by 50%. Essentially, it shows that noise is independent of power consumption of the amplifier. Therefore, whether an operational phase of the ADC is more power intensive or less power intensive does not affect noise of the amplifier.

The present inventors have also found that the transient settling requirements of the ADC are different for different operational phases, in particular different phases of conversion, whereas the noise requirement of the amplifier can be of importance during only one phase of the conversion. Therefore, a low noise requirement and a good settling requirement of the amplifier are not needed simultaneously. As such, it can be sufficient to provide the noise performance and good settling performance at different times, when each is necessary, by controlling the power supply to and therefore changing the power consumption of the ADC. During the conversion phase, the amplifier needs to provide good settling performance, which requires higher power consumption. Conversely, during the acquisition phase or residue amplification phase, when the ADC is not converting, the power consumption can be reduced.

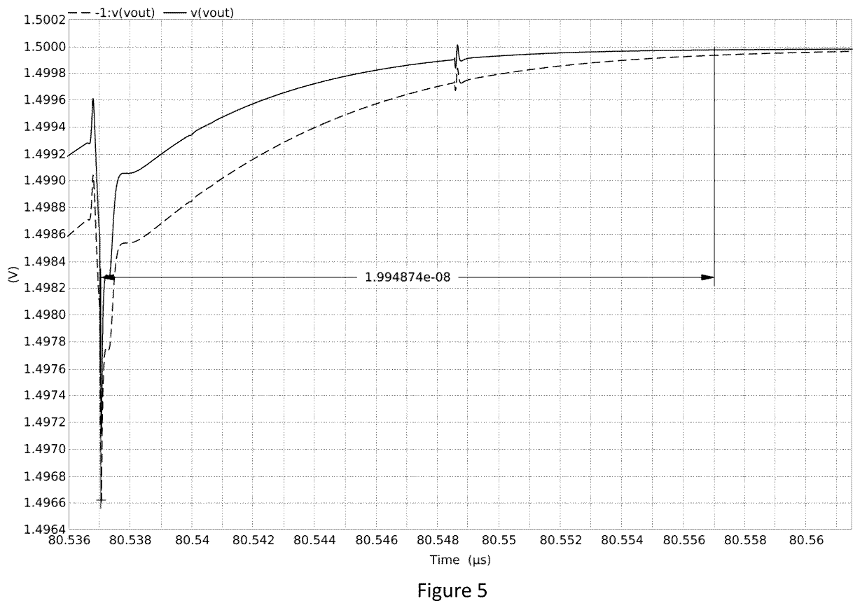

The waveforms shown in FIG. 5 compare the transient settling behavior of the amplifier before and after the impedance scaling as described in the above table of FIG. 4. The time duration for the gain of the amplifier is 20 ns. The amplifier before impedance scaling is shown in the −1:v(vout) plot and the amplifier after impedance scaling is shown in the v(vout) plot. As can be seen in the two plots, the voltages of the of the amplifier before and after impedance scaling differs by only 8 uV, at the end of gain period of the amplifier. For a reference with value of 1.5V, which is less than a LSB of 17-bit ADC.

Based on these principles, a) the power expenditure of the amplifier during operational phase(s) that require quick transient settling should be as much as required to achieve the aforesaid settling requirement. b) however, the power consumption of the amplifier can be reduced during the other operational phase(s) of ADC where either the settling requirements can be relaxed or only noise performance matters, or both.

So, power consumption in the amplifier can be changed as per different operational phases of the ADC, without having to pay a noise penalty. This can be achieved via the implementations of the present disclosure shown in FIGS. 3 and 4.

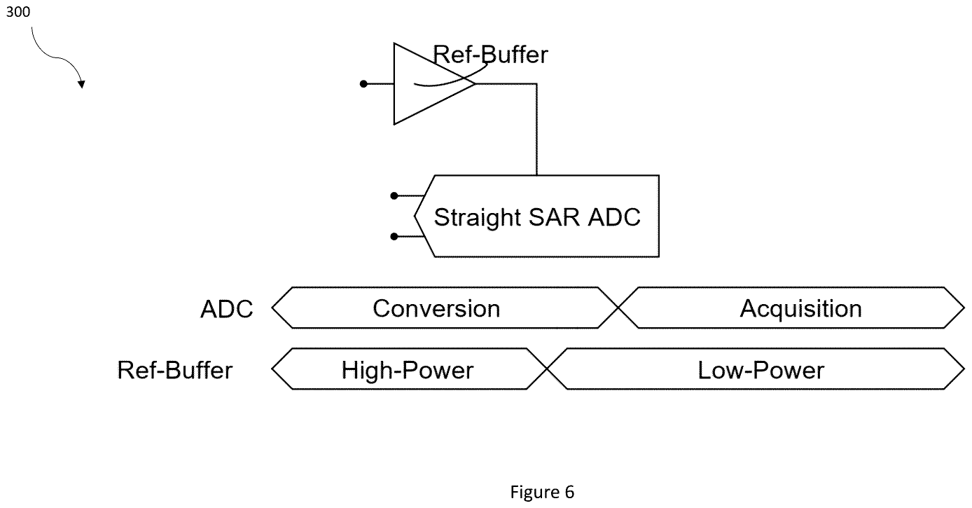

Various use cases of the present disclosure will now be described below in relation to FIGS. 6, 7 and 8. These Figures show SAR ADCs comprising reference circuit, for example, of FIG. 2 or 3. However, a skilled person would appreciate that other types of ADC may be used in accordance with the present disclosure aside from SAR ADC.

FIG. 6 illustrates the operation of an example reference circuit 300 in accordance with an example of the present disclosure. The timing of power scaling of an amplifier, which may be a reference buffer, for the entire operation of a straight SAR ADC is also depicted in FIG. 6.

As the bit trials progress from most-significant-bit (MSB) to least-significant-bit (LSB) in a straight SAR ADC, the reference current and therefore the transient settling requirements on the reference buffer reduce progressively. During the acquisition phase, the reference buffer will have to charge the dither-capacitors, which in general, are smaller than the main capacitor of the DAC.

Therefore, the reference buffer can be put into low-power mode towards the LSB trials of the conversion phase of the ADC and it can remain so throughout the subsequent acquisition phase.

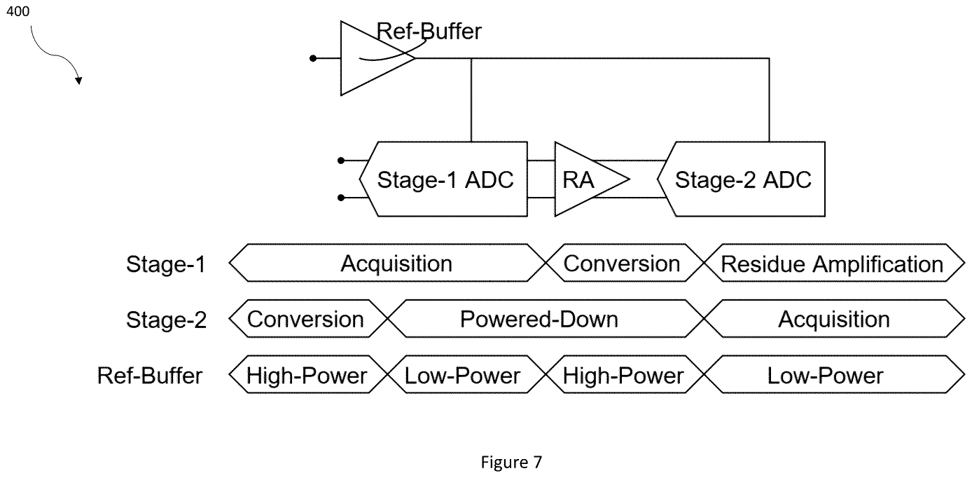

FIG. 7 illustrates the operation of an example reference circuit 500 in accordance with an example of the present disclosure. The timing of power scaling of an amplifier, which may be a reference buffer, for the entire operation of a pipelined SAR ADC is also depicted in FIG. 7.

In a pipelined SAR ADC, the phases of the ADC where the most stringent reference settling requirements can be the redundant bit-trials of the converter. Generally, the time duration of such bit-trials are few nanoseconds (ns). In one or more of such redundant trials, the reference voltage might be needed to settle to the fullest resolution accuracy (for example, 14-b accurate settling for a 14-b ADC etc.).

However, a noise sensitive phase of such an ADC may be its residue amplification phase, which might last for tens of nanoseconds. Although the reference buffer is still required to settle the reference voltage to the fullest resolution accuracy, achieving this settling is not as big a challenge as the redundant trials as there is more time available.

This gives an ideal scenario for the reference buffer to undergo power reduction during the residue amplification phase. As mentioned earlier, since the noise is only dependent on the value of the load capacitance, the power-to-settling trade-off can be made without having to pay the noise penalty.

Another such scenario with pipelined ADCs is the acquisition phase. During this time, the noise as well as settling requirements are not as critical. Therefore, power consumption in the reference buffer can be reduced during the acquisition phase as well.

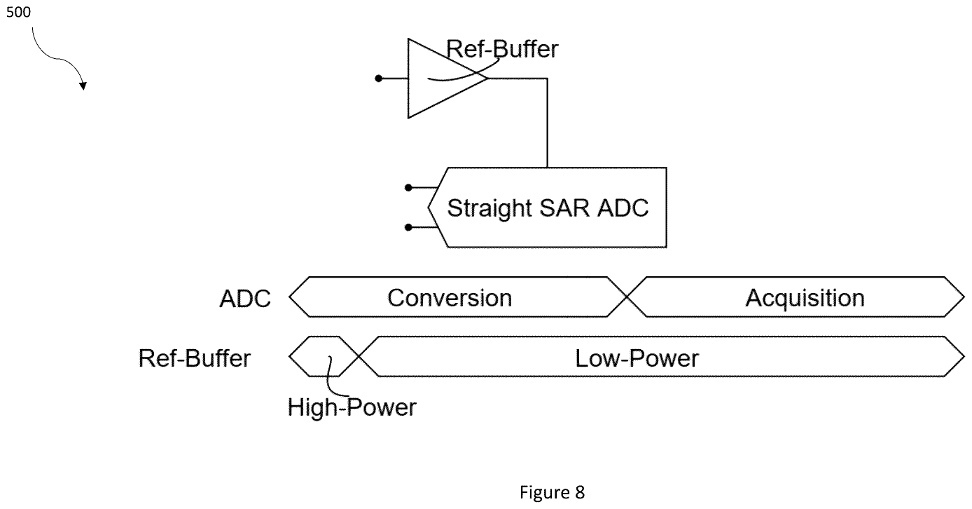

FIG. 8 illustrates the operation of an example reference circuit 500 in accordance with an example of the present disclosure. The timing of power scaling of a reference buffer, using the reference buffer itself as reference pre-charge buffer is also depicted in FIG. 8.

There are various pre-charging techniques, available for reference path. An approach is to use a crude power-cycled amplifier, known as reference pre-charge buffer for providing majority of the reference charge that is typically required in MSB trials of a SAR ADC, and then to let the main reference buffer take over and provide the reference charge for rest of the conversion phase. Reference pre-charge buffers typically have very high UGF and therefore high current consumption and high total integrated noise. However, their usage is for a very short duration of MSB trials. Therefore, they are generally powered off for a majority of the operational cycle of the ADC, thereby making their power consumption a moot point. The high total integrated noise of such amplifiers is of no consequence as the main reference buffer takes over and only its noise matters in critical events such as residue amplification phase or LSB trials for pipelined SAR ADCs and straight SAR ADCs respectively.

A drawback of this technique is the die area required. Separate set of reference switches are required at the bottom-plate of the DAC capacitor of the ADC for the pre-charge buffer, as depicted in FIG. 8. Also, the pre-charge buffer itself needs die-area to begin with. Whenever the realization of a product has very high cost sensitivity, such area expenditures become increasingly important.

Therefore, it is proposed that the main reference buffer itself can be used as reference pre-charge buffer by keeping it in high-power consumption or high-UGF mode in the initial phase of the conversion. Once the MSB trials are loaded, its UGF and therefore power consumption can be reduced for the remainder of the conversion, optimizing both power and area efficiency. The depiction of FIG. 8 assumes a straight-SAR ADC. However, a similar illustration can be made for a pipelined-SAR ADC as well. A particular advantage of these implementations is the avoidance of separate reference switches.

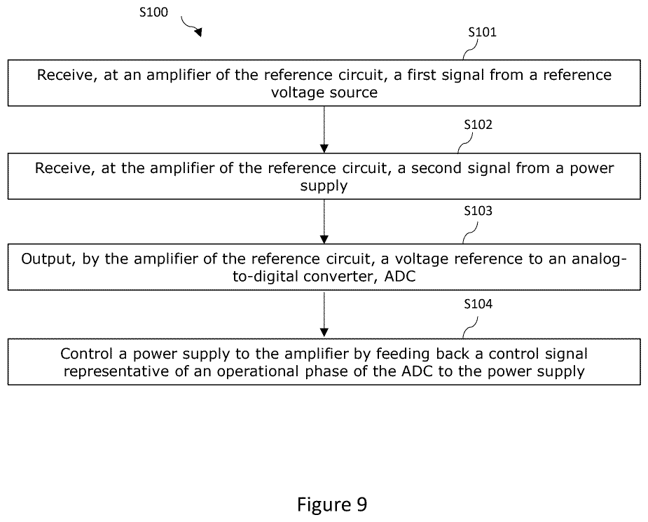

FIG. 9 represents example method steps S100 according to an aspect of the present disclosure. In general, at step S101, a first signal from a reference voltage source is received at an amplifier of the reference circuit. At step S102, a second signal from a power supply is received at the amplifier of the reference circuit. At step S103, a voltage reference is outputted, by the amplifier of the reference circuit, to an analog-to-digital converter, ADC. Finally, at step S104, a power supply to the amplifier is controlled by feeding back a control signal representative of an operational phase of the ADC to the power supply.

The skilled person will readily appreciate that various alterations or modifications may be made to the above-described aspects of the disclosure without departing from the scope of the disclosure. For example, features of two or more of the above examples may be combined and still fall within the scope of the present disclosure.

### Numbered Aspects

By way of non-limiting example, some aspects of the disclosure are set out in the following numbered clauses.

Numbered Clause 1. A method of reducing power consumption in a reference circuit, the method comprising:
receiving, at an amplifier of the reference circuit, a first signal from a reference voltage source;
receiving, at the amplifier of the reference circuit, a second signal from a power supply;
outputting, by the amplifier of the reference circuit, a voltage reference to an analog-to-digital converter, ADC; and
controlling a power supply to the amplifier by feeding back a control signal representative of an operational phase of the ADC to the power supply.

Numbered Clause 2. The method according to Numbered Clause 1, further comprising determining the control signal using digital control circuitry.

Numbered Clause 3. The method according to Numbered Clause 1 or 2, wherein the control signal is received from a timing circuit.

Numbered Clause 4. The method according to any preceding Numbered Clause, wherein controlling the power supply to the amplifier comprises controlling a bias current input from the power supply to the second input of the amplifier.

Numbered Clause 5. The method according to any preceding Numbered Clause, wherein controlling the power supply to the amplifier comprises individually powering down individual slices of the amplifier.

Numbered Clause 6. The method according to any preceding Numbered Clause, wherein controlling the power supply to the amplifier comprises changing the power supply to the amplifier from a first level to a second level.

Numbered Clause 7. The method according to Numbered Clause 6, wherein the first level is higher than the second level.

Numbered Clause 8. The method according to any preceding Numbered Clause, wherein the feeding back the control signal comprising feeding back the control signal representative of a conversion phase of the ADC.

Numbered Clause 9. The method according to Numbered Clause 8, wherein the conversion phase of the ADC comprises a first conversion stage.

Numbered Clause 10. The method according to Numbered Clause 9, wherein the first conversion stage comprising converting a most significant bit, MSB.

Numbered Clause 11. The method according to Numbered Clause 9 or 10, wherein the conversion phase of the ADC comprises a second conversion stage, and wherein controlling a power of the amplifier comprises reducing the power supply to the amplifier from the first conversion stage to the second conversion stage.

Numbered Clause 12. The method according to Numbered Clause 11, wherein the second conversion stage comprises converting a least significant bit, LSB.

Numbered Clause 13. The method according to any preceding Numbered Clause, wherein the feeding back the control signal comprising feeding the control signal representative of an acquisition phase of the ADC, and wherein controlling a power of the amplifier comprises reducing the power supply to the amplifier from a conversion phase to the acquisition phase.

Numbered Clause 14. The method according to any preceding Numbered Clause, wherein the feeding back the control signal comprising feeding the control signal representative of a residue amplification phase of the ADC, and wherein controlling a power of the amplifier comprises reducing the power supply to the amplifier from a conversion phase to the residue amplification phase.

Numbered Clause 15. The method according to any preceding Numbered Clause, further comprising driving an on-chip load capacitor at the output of the amplifier.

Numbered Clause 16. A reference circuit, comprising:
an amplifier configured to act as a voltage amplifier, the amplifier having a first input configured to receive a first signal from a reference voltage source, a second input configured to receive a second signal from a power supply, and an output configured to provide a voltage reference to an analog-to-digital converter, ADC,
wherein a control signal representative of an operational phase of the ADC is configured to be fed back to the power supply in order to control a power supply to the amplifier.

Numbered Clause 17. The reference circuit according to Numbered Clause 16, further comprising digital control circuitry for determining the control signal.

Numbered Clause 18. The reference circuit according to Numbered Clause 17, further comprising generating the control circuitry using the digital control circuitry.

Numbered Clause 19. The reference circuit according to any of Numbered Clauses 16 to 18, further comprising an on-chip load capacitor at the output of the amplifier.

Numbered Clause 20. The reference circuit according to any of Numbered Clauses 16 to 19, further comprising the power supply.

Numbered Clause 21. The reference circuit according to any of Numbered Clauses 16 to 20, wherein the amplifier comprises an operational amplifier.

Numbered Clause 22. The reference circuit according to any of Numbered Clauses 16 to 21, wherein the amplifier comprises a source follower, configured to separate a voltage gain stage and a transconductance device.

Numbered Clause 23. The reference circuit according to any of Numbered Clauses 16 to 22, wherein the amplifier comprises a unity gain buffer amplifier.

Numbered Clause 24. The reference circuit according to any of Numbered Clauses 16 to 23, wherein the amplifier comprises amplifier slices, each slice being configured to be powered down individually.

Numbered Clause 25. A successive approximation register analog-to-digital converter, SAR ADC, comprising the reference circuit of any of Numbered Clauses 16 to 24 and the SAR ADC.

1. A method of reducing power consumption in a reference circuit, the method comprising:
receiving, at an amplifier of the reference circuit, a first signal from a reference voltage source;
receiving, at the amplifier of the reference circuit, a second signal from a power supply;
outputting, by the amplifier of the reference circuit, a voltage reference to an analog-to-digital converter, ADC; and
controlling a power supply to the amplifier by feeding back a control signal representative of an operational phase of the ADC to the power supply.

2. The method according to claim 1, further comprising determining the control signal using digital control circuitry.

3. The method according to claim 1, wherein the control signal is received from a timing circuit.

4. The method according to claim 1, wherein controlling the power supply to the amplifier comprises controlling a bias current input from the power supply to a second input of the amplifier.

5. The method according to claim 1, wherein controlling the power supply to the amplifier comprises individually powering down individual slices of the amplifier.

6. The method according to claim 1, wherein controlling the power supply to the amplifier comprises changing the power supply to the amplifier from a first level to a second level.

7. The method according to claim 6, wherein the first level is higher than the second level.

8. The method according to claim 1, wherein feeding back the control signal comprising feeding back the control signal representative of a conversion phase of the ADC.

9. The method according to claim 8, wherein the conversion phase of the ADC comprises a first conversion stage, wherein the first conversion stage comprising converting a most significant bit, MSB.

10. The method according to claim 9, wherein the conversion phase of the ADC comprises a second conversion stage, and wherein controlling a power of the amplifier comprises reducing the power supply to the amplifier from the first conversion stage to the second conversion stage, wherein the second conversion stage comprises converting a least significant bit, LSB.

11. The method according to claim 1, wherein the feeding back the control signal comprising feeding the control signal representative of an acquisition phase of the ADC, and wherein controlling a power of the amplifier comprises reducing the power supply to the amplifier from a conversion phase to the acquisition phase.

12. The method according to claim 1, wherein the feeding back the control signal comprising feeding the control signal representative of a residue amplification phase of the ADC, and wherein controlling a power of the amplifier comprises reducing the power supply to the amplifier from a conversion phase to the residue amplification phase.

13. The method according to claim 1, further comprising driving an on-chip load capacitor at the output of the amplifier.

14. A reference circuit, comprising:
an amplifier configured to act as a voltage amplifier, the amplifier having a first input configured to receive a first signal from a reference voltage source, a second input configured to receive a second signal from a power supply, and an output configured to provide a voltage reference to an analog-to-digital converter, ADC,
wherein a control signal representative of an operational phase of the ADC is configured to be fed back to the power supply in order to control a power supply to the amplifier.

15. The reference circuit according to claim 14, further comprising digital control circuitry for determining the control signal.

16. The reference circuit according to claim 15, further comprising generating the control signal using the digital control circuitry.

17. The reference circuit according to claim 14, further comprising an on-chip load capacitor at the output of the amplifier.

18. The reference circuit according to claim 14, wherein the amplifier comprises one or more of:
an operational amplifier;
a source follower, configured to separate a voltage gain stage and a transconductance device; and
a unity gain buffer amplifier.

19. The reference circuit according to claim 14, wherein the amplifier comprises amplifier slices, each slice being configured to be powered down individually.

20. The reference circuit according to claim 14, in combination with a successive approximation register analog-to-digital converter, SAR ADC.
